(19) United States
(12) Patent Application Publication
(10) Pub. No.: US 2012/0134126 A1
(43) Pub. Date: May 31, 2012

(54) ELECTRONIC DEVICE

(75) Inventors: TING-TING ZHAO, Shenzhen City (CN); WEI LIU, Shenzhen City (CN); MIN-LI LI, Shenzhen City (CN); YONG-JUN YU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/173,142

(22) Filed: Jun. 30, 2011

(30) Foreign Application Priority Data
Nov. 29, 2010 (CN) 201010564481.0

(51) Int. Cl. H05K 7/00

(52) U.S. Cl. 361/807

(57) ABSTRACT

An electronic device includes a housing, a lid, and at least one connection structure. The housing includes an upper housing and a lower housing engaged with the upper housing. The lid is connected to the housing and covering a part of the upper housing. The at least one connection structure is used for connecting the lower housing with the upper housing. Each connection structure includes a connection post protruding from an interior surface of the lower housing and a connection member passing through the part of the upper housing covered by the lid communicate with the lower housing for engagement with the connection post.

### BACKGROUND

1. Technical Field

The present disclosure relates to a housing for an electronic device.

2. Description of Related Art

Many electronic devices, such as optical disk players, often include a housing for receiving various components for the operation of the electronic device. The housing often includes an upper cover and a lower cover connected to the upper cover with screws. Generally, a plurality of through holes that extend from the lower cover to the upper cover are defined in the lower cover, while a plurality of connection posts extend downward and correspond to the plurality of through holes that are disposed on the interior surface of the upper cover. The plurality of screws pass through the through holes respectively and screw into the connection posts to connect the lower cover to the upper cover. In some cases, the lower cover may be provided with a curved sidewall, and some of the through holes may be defined in the curved sidewall. When a through hole is defined in the curved sidewall, the through hole with a screw may be easily seen, which may reduce the aesthetics of the housing.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of an electronic device according to an embodiment of the present disclosure. The electronic device includes a lid in an open state.

FIG. 2 is a side view of the electronic device of FIG. 1 with the lid in a closed state.

FIG. 3 is similar to FIG. 2 but seen from another angle.

FIG. 4 is an exploded view of the electronic device of FIG. 1.

### DETAILED DESCRIPTION

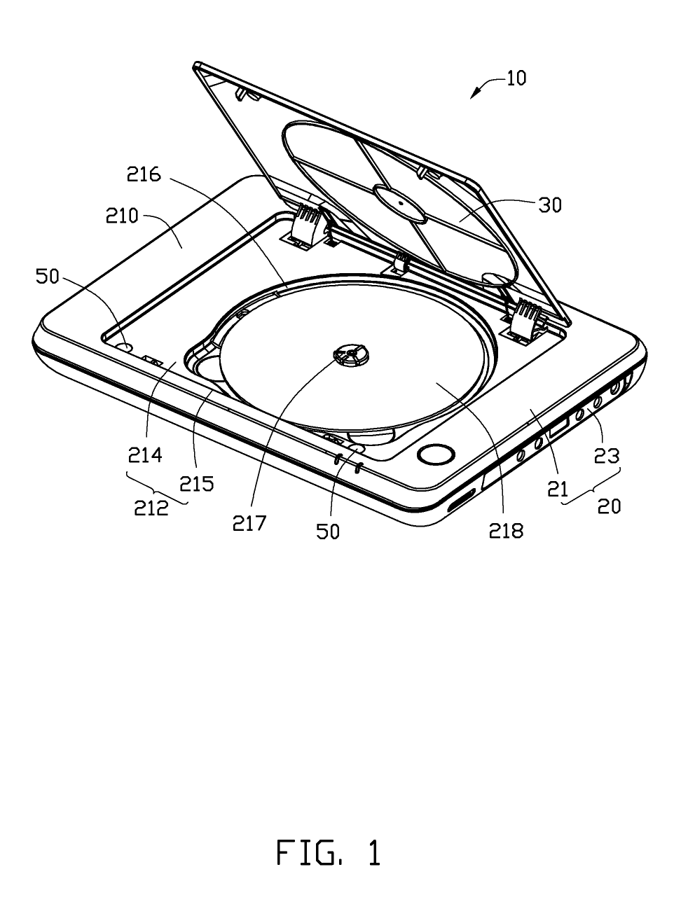

Referring to FIG. 1, an electronic device 10 in accordance with an embodiment includes a housing 20 and a lid 30 pivotally connected to the housing 20. The housing 20 is used for accommodating various components of the electronic device 10. The lid 30 covers a part of the housing 20. In the illustrated embodiment, the electronic device 10 is an optical disk player, and the lid 30 covers a disk clipped in the housing 20.

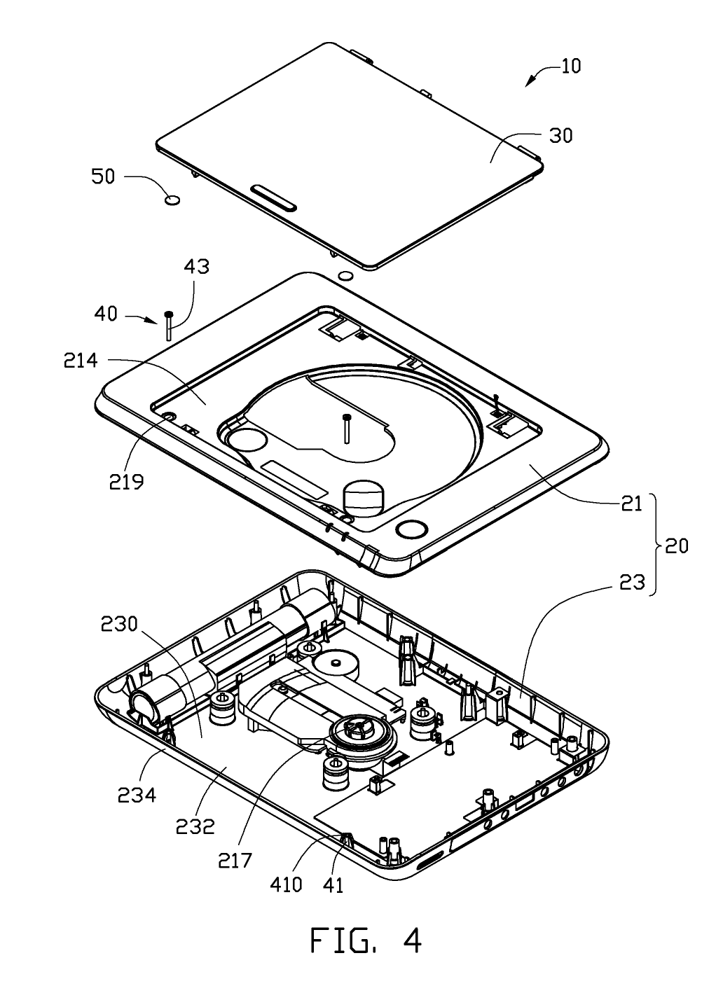

In the illustrated embodiment, the housing includes an upper housing 21 and a lower housing 23 attached to the upper housing 21. A first depression 212 is defined in a top surface 210 of the upper housing 21 for accommodating the lid 30. The first depression 212 includes two walls 214 and 215. A second depression 216 is defined in the wall 214 with a rotator 217 located therein. A disk 218 is clipped on the rotator 217 and is received in the second depression 216. Referring also to FIG. 4, two connection holes 219 are defined in the wall 214 of the first depression 212, adjacent to the wall 215.

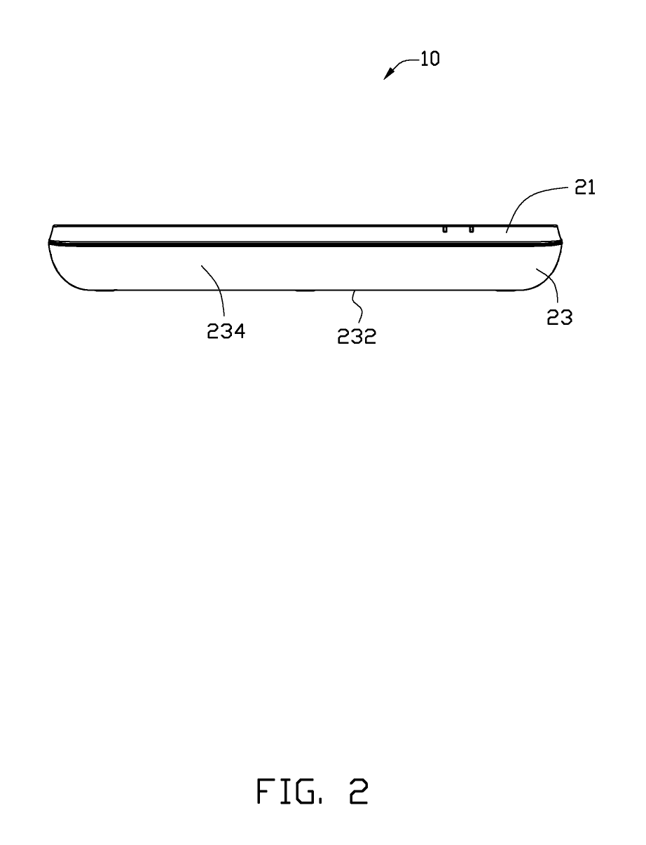

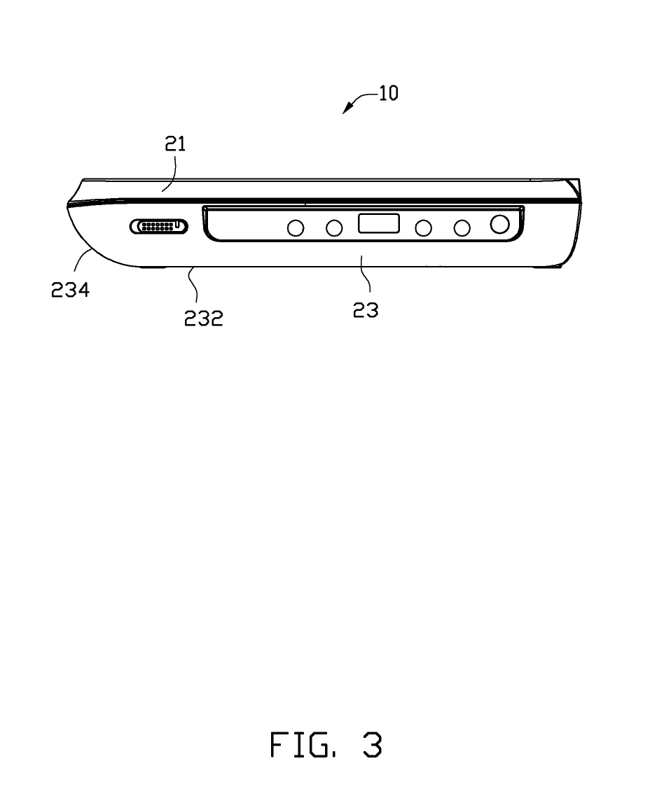

Also referring to FIGS. 2 and 3, the lower housing 23 includes a bottom wall 232 and a side wall 234 extending upwards from the bottom wall 232. In the illustrated embodiment, the side wall 234 is convexly curved and arc shaped.

Referring also to FIG. 4, the electronic device 10 further includes two connection structures 40 for connecting the upper housing 21 to the lower housing 23. Each connection structure 40 includes a connection post 41 connected to the lower housing 23 with a connection member 43 passing through the connection hole 219 defined in the upper housing 21 to be connected to the connection post 41. Each connection post 41 protrudes upwards from an interior surface of the side wall 234 of the lower housing 23 and is substantially perpendicular to the bottom wall 232. A screw hole 410 is defined in each connection post 41. Each connection member 43 is inserted in the corresponding connection hole 219 to extend into the screw hole 410 of the corresponding connection post 41. In some embodiments, the connection members 43 may be screws adapted to screw into the connection posts 41 respectively.

Referring to both FIGS. 1 and 4, the electronic device 10 further includes two covering members 50 disposed on the upper housing 21 corresponding to the connection holes 219 covering the connection members 43 respectively disposed in the connection holes 219. In the embodiment, the covering members 50 are made of elastic material.

The connection posts 41 protrude from the interior space of the side wall 234 of the lower housing 23. The connection holes 219 are defined in the wall 214 of the first depression 212, and the covering members 50 cover the connection members 41, therefore, the connection members 43 are invisible to users when users look at the side wall 234 or even the wall 214 of the first depression 212 of the upper housing.

It is to be understood, however, that even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An electronic device, comprising:
a housing comprising an upper housing and a lower housing engaged with the upper housing;
a lid connected to the housing and covering a part of the upper housing; and
at least one connection structure for connecting the lower housing with the upper housing, the at least one connection structure comprising:
a connection post protruding from an interior surface of the lower housing; and
a connection member passing through the part of the upper housing covered by the lid to the lower housing to engage with the connection post.

2. The electronic device as claimed in claim 1, wherein the lower housing comprises a bottom wall and a curved side wall protruding from the bottom wall.

3. The electronic device as claimed in claim 2, wherein the side wall is convexly curved.

4. The electronic device as claimed in claim 3, wherein the connection post protrudes from an interior surface of the side wall and is substantially perpendicular to the bottom wall.

5. The electronic device as claimed in claim 3, wherein at least one connection hole is defined in the part of the upper housing covered by the lid for passing the connection member through.

6. The electronic device as claimed in claim 5, wherein the connection member is a screw inserted in the connection hole.

7. The electronic device as claimed in claim 5, wherein a screw hole is defined in the connection post to correspond to the connection hole for screwing the connection post therein.

8. The electronic device as claimed in claim 7, wherein the electronic device further comprises at least one covering member disposed in the connection hole for covering the connection member.

9. The electronic device as claimed in claim 5, wherein the electronic device is an optical disk player, a first depression is formed in the upper housing for accommodating the lid, the first depression comprises a wall corresponding to the part of the housing covered by the lid, a second depression is formed in the wall of the first depression for receiving a disk.

10. The electronic device as claimed in claim 9, wherein the at least one connection hole is defined in the wall of the first depression.

11. The electronic device as claimed in claim 10, wherein the electronic device further comprises at least one covering member disposed in the at least one connection hole for covering each connection member.

12. The electronic device as claimed in claim 11, wherein the covering member is coplanar with the wall of the recession.

13. The electronic device as claimed in claim 11, wherein the covering member is made of elastic material.

14. The electronic device as claimed in claim 11, wherein a screw hole is defined in each connection post to correspond to the connection hole, the connection member is inserted in the connection hole and screw hole.

15. An electronic device, comprising:
a housing comprising an upper housing and a lower housing engaged with the upper housing; and
at least one connection structure for connecting the lower housing with the upper housing, each connection structure comprising:
a connection post protruding from an interior surface of the lower housing;
a connection member passing through the upper housing to get into the lower housing to engage with the connection post; and
at least one covering member disposed on the upper housing to cover the connection member of the at least one connection member.

16. The electronic device as claimed in claim 15, wherein the lower housing comprises a bottom wall and a convexly curved side wall protruding from the bottom wall.

17. The electronic device as claimed in claim 16, wherein the connection post protrudes from an interior surface of the side wall and is substantially perpendicular to the bottom wall.

18. The electronic device as claimed in claim 17, wherein a connection hole is defined in the upper housing, and the connection member is inserted in the connection hole to engage with the connection post.

19. The electronic device as claimed in claim 18, wherein the covering member is inserted in the connection hole to cover the connection member.

20. The electronic device as claimed in claim 19, wherein the covering member is made of elastic member.
